(19) United States
(12) Patent Application Publication
(10) Pub. No.: US 2012/0112209 A1
(43) Pub. Date: May 10, 2012

(54) SILICON CARBIDE SUBSTRATE FABRICATION METHOD, SEMICONDUCTOR DEVICE FABRICATION METHOD, SILICON CARBIDE SUBSTRATE, AND SEMICONDUCTOR DEVICE

(75) Inventors: Taro Nishiguchi, Hyogo (JP); Shin Harada, Osaka (JP); Hiroki Inoue, Hyogo (JP); Makoto Sasaki, Hyogo (JP)

(73) Assignee: SUMITOMO ELECTRIC INDUSTRIES, LTD., Osaka-shi, Osaka (JP)

(21) Appl. No.: 13/382,374

(22) PCT Filed: Feb. 25, 2011
(86) PCT No.: PCT/JP2011/054341

§ 371 Date: Jan. 5, 2012

(30) Foreign Application Priority Data
May 14, 2010 (JP) 2010 111977

(51) Int. Cl. H01L 29/24; H01L 21/20; H01L 21/30

(52) U.S. Cl. 257/77; 438/455; 438/478; 257/E21.09; 257/E21.211; 257/E29.104

(57) ABSTRACT

A method of fabricating a silicon carbide substrate that can reduce the fabrication cost of a semiconductor device employing the silicon carbide substrate includes the steps of: preparing a SiC substrate made of single crystal silicon carbide; arranging a base substrate in a vessel so as to face one main face of the SiC substrate; forming a base layer made of silicon carbide so as to contact one main face of the SiC substrate by heating a base substrate to a temperature range greater than or equal to a sublimation temperature of silicon carbide constituting the base substrate. In the step of forming a base layer, a silicon generation source made of a substance including silicon is arranged in the vessel, in addition to the SiC substrate and the base substrate.

### TECHNICAL FIELD

The present invention relates to a method of fabricating a silicon carbide substrate, a method of fabricating a semiconductor device, a silicon carbide substrate, and a semiconductor device. More particularly, the present invention relates to a method of fabricating a silicon carbide substrate allowing reduction in the fabrication cost of a semiconductor device employing the silicon carbide substrate, a method of fabricating a semiconductor device, a silicon carbide substrate, and a semiconductor device.

### BACKGROUND ART

In recent years, the adoption of silicon carbide as the material for forming a semiconductor device is in progress in order to allow a high breakdown voltage, low loss and usage under a high temperature environment for semiconductor devices. Silicon carbide is a wide band gap semiconductor having a band gap greater than that of silicon that has been widely used conventionally as a material constituting a semiconductor device. By employing silicon carbide as the material constituting a semiconductor device, a high breakdown voltage and reduction in the on resistance for a semiconductor device can be achieved. A semiconductor device employing silicon carbide as the material is also advantageous in that reduction in the property when used under a high temperature environment is small as compared to a semiconductor device employing silicon as the material.

Under such a situation, various study has been done on silicon carbide crystal employed in the fabrication of a semiconductor device as well as the method of fabricating a silicon carbide substrate, leading to various proposals (for example, refer to Japanese Patent Laying-Open No. 2002-280531 (Patent Literature 1)).

### CITATION LIST

### Patent Literature

PTL 1: Japanese Patent Laying-Open No. 2002-280531

### SUMMARY OF INVENTION

### Technical Problem

Silicon carbide does not achieve a liquid phase under ordinary pressure. Furthermore, the crystal growth temperature is at least 2000° C., which is extremely high, and the growth condition is hard to control and stabilize. It was therefore difficult to increase the size of silicon carbide single crystal while maintaining high quality. It was not easy to obtain a silicon carbide substrate of large diameter and high quality. Due to the difficulty in producing a silicon carbide substrate of large diameter, the fabrication cost of a silicon carbide substrate will become higher. In addition, in producing a semiconductor device using such a silicon carbide substrate, the number of products per 1 batch is reduced, leading to the problem that the fabrication cost of semiconductor devices is increased. It is considered that the fabrication cost of a semiconductor device can be reduced by utilizing silicon carbide single crystal that has a high fabrication cost effectively as the substrate.

In view of the foregoing, an object of the present invention is to provide a method of fabricating a silicon carbide substrate allowing reduction in the fabrication cost of a semiconductor device employing the silicon carbide substrate, a method of fabricating a semiconductor device, a silicon carbide substrate, and a semiconductor device.

### Solution to Problem

A method of fabricating a silicon carbide substrate according to the present invention includes the steps of preparing a SiC substrate made of single crystal silicon carbide, arranging a silicon carbide source in a vessel so as to face one main face of the SiC substrate, and forming a base layer made of silicon carbide so as to contact one main face of the SiC substrate by heating the silicon carbide source in the vessel to a temperature range greater than or equal to a sublimation temperature of silicon carbide constituting the silicon carbide source. In the step of forming a base layer, a silicon generation source made of a substance containing silicon is arranged in the vessel, in addition to the SiC substrate and silicon carbide source.

As mentioned above, it is difficult to increase the diameter of silicon carbide single crystal having high quality. In order to carry out fabrication efficiently in the process of fabricating a semiconductor device employing a silicon carbide substrate, a substrate standardized in a predetermined shape and size is required. Even if a silicon carbide single crystal of high quality (for example, a silicon carbide single crystal with low defect density) is obtained, there is a possibility of a region not being utilized effectively since it cannot be worked to a predetermined shape or the like by cutting.

According to a method of fabricating a silicon carbide substrate of the present invention, a base layer is formed so as to contact one main face of a SiC substrate made of single crystal silicon carbide. Therefore, a base layer made of low-quality silicon carbide crystal can be formed in a predetermined shape and size, while silicon carbide single crystal of high quality, but not realized in a desired shape and the like, can be employed for a SiC substrate. A silicon carbide substrate fabricated by such a process can contribute to improving the efficiency in fabricating a semiconductor device since the substrate is standardized in a predetermined shape and size as a whole. By a silicon carbide substrate fabricated through such a process, a semiconductor device can be produced utilizing a SiC substrate made of silicon carbide single crystal of high quality that was not conventionally utilized by not being able to be worked to a desired shape. Therefore, silicon carbide single crystal can be used effectively.

According to a method of fabricating a silicon carbide substrate of the present invention, there can be provided a method of fabricating a silicon carbide substrate that allows the fabrication cost of a semiconductor device employing the silicon carbide substrate to be reduced.

In the method of fabricating a silicon carbide substrate set forth above, there is an event of the formation of a base layer not proceeding sufficiently. By a study made by the inventors, the cause thereof was identified as set forth below. Formation of a base layer is achieved by heating a silicon carbide source to a temperature range greater than or equal to the sublimation temperature of silicon carbide. In forming a base layer, the silicon carbide constituting the silicon carbide source sublimes to be converted into sublimation gas, which is then recrystallized on the SiC substrate. This sublimation gas is obtained by sublimation of solid silicon carbide, including, for example, Si, Si₂C, SiC₂, or the like. However, in the case where the vapor pressure of the sublimation gas in the vessel where formation of a base layer is performed is less than the saturation vapor pressure, silicon that has a vapor pressure higher than that of carbon will be selectively (preferentially) disengaged from the silicon carbide. Accordingly, the region in the proximity of the surface of the silicon carbide source will be carbonized (become graphite). As a result, sublimation of silicon carbide is impeded to decay the progress of base layer formation.

In a step of forming a base layer in the method of fabricating a silicon carbide substrate of the present invention, a silicon generation source formed of a substance containing silicon is arranged in the vessel where the step of forming a base layer is carried out, in addition to the SiC substrate and the silicon carbide source. Accordingly, the silicon constituting the silicon generation source is vaporized to increase the vapor pressure of silicon. Therefore, the carbonization of the silicon carbide source caused by the aforementioned selective disengagement of silicon is suppressed. As a result, formation of a base layer through sublimation and recrystallization from the silicon carbide source proceeds smoothly.

In the method of fabricating a silicon carbide substrate set forth above, graphite may be used for the material constituting the vessel.

Graphite is advantageous in that it is stable at high temperature, readily worked, and has a relatively low material cost. Therefore, graphite is suitable as the material of the vessel employed in a step requiring heating of a silicon carbide source to a temperature range greater than or equal to the sublimation temperature of silicon carbide.

In the method of fabricating a silicon carbide substrate set forth above, a coating layer may be formed at the inner wall of the vessel to suppress reaction between the graphite constituting the vessel and silicon.

In the case where graphite (carbon) is employed as the material constituting the vessel, the silicon vapor generated from the silicon generation source will react with carbon to be consumed, leading to the possibility of impeding the rise of the silicon vapor pressure. By the formation of a coating layer on the inner wall of the vessel, reaction between the silicon vapor and carbon will be suppressed. As a result, carbonization of the silicon carbide source can be suppressed.

In the method of fabricating a silicon carbide substrate set forth above, the coating layer may include at least one substance selected from the group consisting of tantalum, tantalum carbide and silicon carbide. Tantalum, tantalum carbide and silicon carbide are stable at high temperature, and have a low reactivity with silicon. Therefore, these substances are suitable as the material constituting the coating layer.

In the method of fabricating a silicon carbide substrate set forth above, the vessel may be made of tantalum carbide. By employing tantalum carbide as the material of the vessel, carbonization of the silicon carbide source can be suppressed effectively even if formation of a coating layer is dispensed with.

In the step of preparing a SiC substrate in the method of fabricating a silicon carbide substrate set forth above, a plurality of SiC substrates may be prepared. In the step of arranging a silicon carbide source, the silicon carbide source is arranged under a state where the plurality of SiC substrates are arranged in alignment in plan view. In the step of forming a base layer, the base layer may be formed such that one main faces of the plurality of SiC substrates are connected to each other.

As mentioned above, it is difficult to increase the diameter of silicon carbide single crystal having high quality. Upon arranging a plurality of SiC substrates, obtained from high-quality silicon carbide single crystal, in alignment in plan view, and forming a base layer such that one main faces of the plurality of SiC substrates contact each other, a silicon carbide substrate capable of being handled as a substrate of large diameter having a high-quality SiC layer can be obtained. Furthermore, by employing such a silicon carbide substrate, the fabrication process of a semiconductor device can be rendered efficient. In order to render efficient the process of fabricating a semiconductor device, SiC substrates adjacent to each other among the plurality of SiC substrates are preferably arranged in contact with each other. More specifically, the plurality of SiC substrates are preferably arranged in a matrix in plan view.

In the step of arranging a silicon carbide source in the method of fabricating a silicon carbide substrate, a base substrate made of silicon carbide, qualified as the silicon carbide source, is arranged such that one main face of the base substrate and one main face of the SiC substrate face each other in contact. In the step of forming a base layer, a base layer may be formed having a base substrate connected to the SiC substrate by the base substrate being heated. By employing a base substrate formed of silicon carbide as the silicon carbide source, a base layer can be formed readily.

The method of fabricating a silicon carbide substrate may further include the step of planarizing main faces of the base substrate and the SiC substrate to be brought into contact with each other at the step of arranging a silicon carbide source, prior to the step of arranging a silicon carbide source. Accordingly, by planarizing in advance the face that will be the connecting face of the base substrate and SiC substrate, the base substrate and SiC substrate can be connected more reliably.

In the method of fabricating a silicon carbide substrate set forth above, the step of arranging a silicon carbide source may be carried out without polishing the main faces of the base substrate and SiC substrate that are to be brought into contact with each other in the step of arranging a silicon carbide source, prior to the step of arranging a silicon carbide source.

Accordingly, the fabrication cost of a silicon carbide substrate can be reduced. The main faces of the base substrate and SiC substrate to be brought into contact with each other in the step of arranging a silicon carbide source may not have to be polished as set forth above. However, from the standpoint of removing any damage layer in the proximity of the surface formed by slicing or the like at the stage of producing a substrate, the step of arranging a silicon carbide source is preferably carried out after the step of removing a damage layer by etching is carried out.

In the step of arranging a silicon carbide source according to the method of fabricating a silicon carbide substrate set forth above, a material substrate made of silicon carbide qualified as a silicon carbide source is arranged such that one main face of the material substrate and one main face of the SiC substrate face each other with a distance therebetween. In the step of forming a base layer, the material substrate may be heated to cause sublimation of silicon carbide constituting the material substrate to form a base layer. By employing a material substrate made of silicon carbide as the silicon carbide source, a base layer can be readily formed.

In the step of forming a base layer according to the method of fabricating a silicon carbide substrate set forth above, the silicon carbide source is preferably heated to a temperature higher than that of the SiC substrate. Accordingly, mainly the silicon carbide constituting the silicon carbide source, among the SiC substrate and silicon carbide source, is sublimated and recrystallized. As a result, a base layer can be formed while maintaining the quality such as the crystallinity of the SiC substrate.

In the step of forming a base layer according to the method of fabricating a silicon carbide substrate set forth above, a base layer may be formed such that an off angle of a main face of the SiC substrate at a side opposite to the base layer is greater than or equal to 50° and less than or equal to 65° relative to a {0001} plane.

A hexagonal single crystal silicon carbide being grown in a <0001> direction allows a single crystal of high quality to be produced efficiently. From a silicon carbide single crystal grown in the <0001> direction, a silicon carbide substrate with the {0001} plane as the main face can be employed efficiently. By using a silicon carbide substrate having a main face whose off angle relative to plane orientation {0001} is greater than or equal to 50° and less than or equal to 65°, there may be a case where a semiconductor device of high performance can be fabricated.

Specifically, a silicon carbide substrate used in the production of an MOSFET (Metal Oxide Semiconductor Field Effect Transistor), for example, generally has a main face whose off angle relative to plane orientation {0001} is less than or equal to approximately 8°. An epitaxial growth layer is formed on the main face, followed by formation of an oxide film, an electrode and the like on the epitaxial growth layer to obtain an MOSFET. In this MOSFET, a channel region is formed at the region including the interface between the epitaxial growth layer and the oxide film. At such an MOSFET of the configuration set forth above, many interface states will be formed in the proximity of the interface between the epitaxial growth layer and the oxide film where a channel region is formed due to the off angle of the main face of the substrate relative to plane orientation {0001} being less than or equal to approximately 8°. This will impede the running of the carriers, leading to degradation in the channel mobility.

However, by forming a base layer such that the main face of the SiC substrate at the side opposite to the base layer has an off angle greater than or equal to 50° and less than or equal to 65° relative to the {0001} plane in the step of forming a base layer, the off angle of the main face of the produced silicon carbide substrate relative to the {0001} plane will be greater than or equal to 50° and less than or equal to 65°. Accordingly, formation of an interface state set forth above is reduced. There can be fabricated a silicon carbide substrate allowing the production of an MOSFET or the like having the on resistance reduced.

In the step of forming a base layer according to the method of fabricating a silicon carbide substrate set forth above, the base layer may be formed such that the angle between the off orientation of the main face of the SiC substrate at the side opposite to the base layer and the <1-100> direction is less than or equal to 5°.

The <1-100> direction is an off orientation typical of a silicon carbide substrate. By setting the variation in the off orientation caused by variation in the slicing process during the fabrication process of a substrate less than or equal to 5°, formation of an epitaxial growth layer on a SiC substrate can be facilitated.

In the step of forming a base layer according to the method of fabricating a silicon carbide substrate set forth above, a base layer may be formed such that a main face of the SiC substrate at the side opposite to the base layer has an off angle greater than or equal to −3° and less than or equal to 5° relative to a {03-38} plane in the <1-100> direction.

Accordingly, the channel mobility can be further improved in the case where an MOSFET or the like is produced using a silicon carbide substrate. The reason why the off angle relative to plane orientation {03-38} is set greater than or equal to −3° and less than or equal to 5° is based on the fact that particularly high channel mobility can be achieved within this range as a result of examining the relationship between the channel mobility and off angle.

As used herein, “the off angle relative to the {03-38} plane in the <1-100> direction” refers to the angle between the orthogonal projection of the normal line of the main surface on the projecting plane defined by the <1-100> direction and <0001> direction and the normal line of the {03-38} plane. The sign is positive when the aforementioned orthogonal projection approaches the <1-100> direction in parallel, and negative when the aforementioned orthogonal projection approaches the <0001> direction in parallel.

The aforementioned plane orientation of the main face substantially is more preferably {03-38}, further preferably {03-38}. As used herein, the plane orientation of the main face substantially being {03-38} implies that the plane orientation of the main face of the substrate is included in the range of the off angle in which the plane orientation can be substantially taken as {03-38} in consideration of the working accuracy or the like of the substrate. In this case, the range of the off angle is, for example, ±2° relative to {03-38}. Accordingly, the aforementioned channel mobility can be further improved.

In the step of forming a base layer according to the method of fabricating a silicon carbide substrate set forth above, a base layer may be formed such that the angle between the off orientation of the main face of the SiC substrate at the side opposite to the base layer and the <11-20> direction is less than or equal to 5°.

The <11-20> direction is a typical off orientation of a silicon carbide substrate, likewise with the aforementioned <1-100> direction. By setting the variation in the off orientation caused by variation in the slicing process in the step of fabricating a substrate to ±5°, an epitaxial growth layer can be readily formed on the SiC substrate.

In the method of forming a base layer according to the method of fabricating a silicon carbide substrate set forth above, a base layer may be formed in an atmosphere obtained by reducing an ambient air atmosphere. Accordingly, the fabrication cost of a silicon carbide substrate can be reduced.

In the step of forming a base layer according to the method of fabricating a silicon carbide substrate set forth above, a base layer may be formed under a pressure higher than 10⁻¹ Pa and lower than 10⁴ Pa. Accordingly, the above-described base layer can be formed by a simple apparatus, and an atmosphere for carrying out formation of a base layer in a relatively short time is allowed. As a result, the fabrication cost of a silicon carbide substrate can be reduced.

A method of fabricating a semiconductor device according to the present invention includes the steps of preparing a silicon carbide substrate, forming an epitaxial growth layer on the silicon carbide substrate, and forming an electrode on the epitaxial growth layer. In the step of preparing a silicon carbide substrate, a silicon carbide substrate is fabricated by the above-described method of fabricating a silicon carbide substrate.

According to a method of fabricating a semiconductor device of the present invention, the fabrication cost of a semiconductor device can be reduced since the semiconductor device is fabricated using a silicon carbide substrate fabricated by the above-described method of fabricating a silicon carbide substrate of the present invention.

A silicon carbide substrate according to the present invention is fabricated by the above-described method of fabricating a silicon carbide substrate of the present invention. Accordingly, the silicon carbide substrate of the present invention allows reduction in the fabrication cost of a semiconductor device employing the silicon carbide substrate.

A semiconductor device according to the present invention is fabricated by the above-described method of fabricating a semiconductor device of the present invention. Accordingly, the semiconductor device of the present invention has the fabrication cost reduced.

### Advantageous Effects of Invention

As apparent from the description set forth above, by virtue of a method of fabricating a silicon carbide substrate, a method of fabricating a semiconductor device, a silicon carbide substrate, and a semiconductor device of the present invention, there can be provided a method of fabricating a silicon carbide substrate that can have the fabrication cost of a semiconductor device employing the silicon carbide substrate reduced, a method of fabricating a semiconductor device, a silicon carbide substrate, and a semiconductor device.

### BRIEF DESCRIPTION OF DRAWINGS

FIG. 1 is a flowchart schematically representing a method of fabricating a silicon carbide substrate.

FIG. 2 is a schematic sectional view to describe a method of fabricating a silicon carbide substrate.

FIG. 3 is a schematic sectional view representing a configuration of a silicon carbide substrate.

FIG. 4 is a schematic sectional view to describe a method of fabricating a silicon carbide substrate according to a second embodiment.

FIG. 5 is a flowchart schematically representing a method of fabricating a silicon carbide substrate according to a third embodiment.

FIG. 6 is a schematic sectional view to describe the method of fabricating a silicon carbide substrate according to the third embodiment.

FIG. 7 is a schematic sectional view to describe the method of fabricating a silicon carbide substrate according to the third embodiment

FIG. 8 is a schematic sectional view to describe the method of fabricating a silicon carbide substrate according to the third embodiment.

FIG. 9 is a schematic sectional view to describe a method of fabricating a silicon carbide substrate according to a fourth embodiment.

FIG. 10 is a schematic sectional view representing a configuration of a silicon carbide substrate according to the fourth embodiment.

FIG. 11 is a schematic sectional view representing a configuration of a vertical MOSFET.

FIG. 12 is a flowchart schematically representing a method of fabricating a vertical MOSFET.

FIG. 13 is a schematic sectional view to describe a method of fabricating a vertical MOSFET.

FIG. 14 is a schematic sectional view to describe a method of fabricating a vertical MOSFET.

FIG. 15 is a schematic sectional view to describe a method of fabricating a vertical MOSFET.

FIG. 16 is a schematic sectional view to describe a method of fabricating a vertical MOSFET.

### DESCRIPTION OF EMBODIMENTS

Embodiments of the present invention will be described hereinafter with reference to the drawings. In the drawings, the same or corresponding elements have the same reference characters allotted, and description thereof will not be repeated.

### First Embodiment

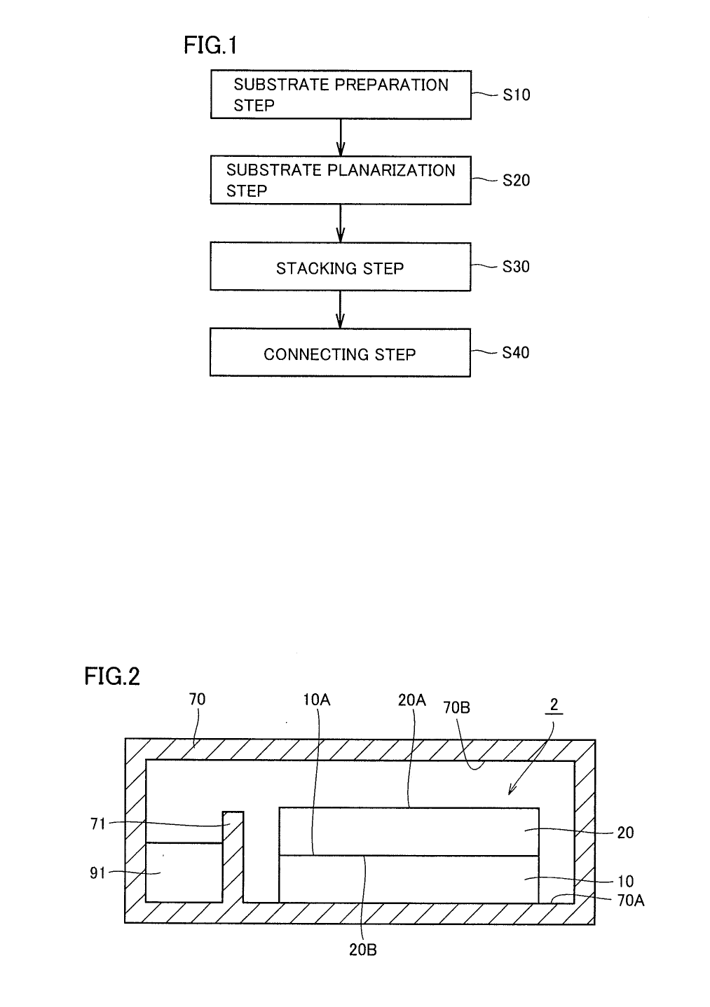

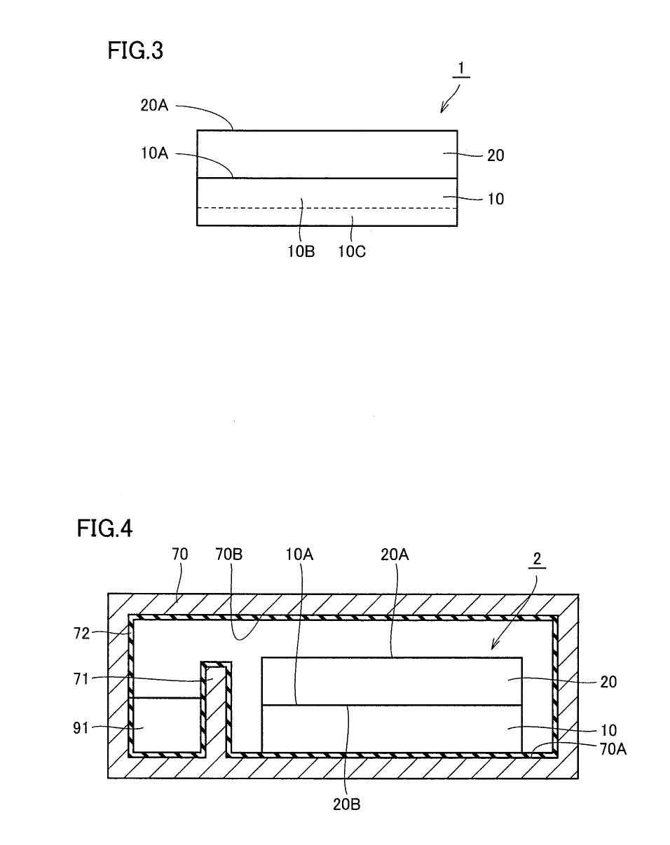

A first embodiment that is one embodiment of the present invention will be described hereinafter with reference to FIGS. 1 and 2. Referring to FIG. 1, in a method of fabricating a silicon carbide substrate according to the present embodiment, a substrate preparation step is carried out as step S10. In this step S10, a base substrate 10 made of silicon carbide and a SiC substrate 20 made of single crystal silicon carbide are prepared. Base substrate 10 serves as a silicon carbide source in the present embodiment. A main face 20A of SiC substrate 20 will become a main face 20A of a SiC layer 20 obtained by the present fabrication method (refer to FIG. 3 that will be described afterwards). Therefore, the plane orientation of main face 20A of SiC substrate 20 is selected according to the desired plane orientation of main face 20A. For base substrate 10, a substrate having an impurity concentration greater than 2×10¹⁹ cm⁻³ is employed. For SiC substrate 20, a substrate having an impurity concentration greater than 5×10¹⁸ cm⁻³ and lower than 2×10¹⁹ cm⁻³ can be employed. Accordingly, generation of a stacked defect can be suppressed at at least SiC layer 20 even in the case where a base layer 10 of low resistivity is formed and thermal treatment is carried out in the device process. Further, for base substrate 10, a substrate made of single crystal silicon carbide, polycrystal silicon carbide, amorphous silicon carbide, silicon carbide sintered compact, or the like may be employed.

Then, a substrate planarization step is carried out as step S20. In this step S20, main face 10A of base substrate 10 and main face 20B of SiC substrate 20 that are to be brought into contact with each other (connecting face) at a step that will be described afterwards (S30) are planarized by, for example, polishing. Although this step S20 is not mandatory, the size of the gap between base substrate 10 and SiC substrate 20 facing each other will become uniform by carrying out this step, allowing the uniformity of the reaction (connection) in the connecting face at a step S40 that will be described afterwards is improved. As a result, the connection between base substrate 10 and SiC substrate 20 can be further ensured. For a more reliable connection between base substrate 10 and SiC substrate, the surface roughness Ra of the connecting face is preferably less than 100 nm, preferably less than 50 nm. By setting the surface roughness Ra of the connecting plane less than 10 nm, a further reliable connection can be achieved.

It is to be noted that step S20 may be omitted, and step S30 may be carried out without polishing the main faces of base substrate 10 and SiC substrate 20 that are to be brought into contact with each other. Accordingly, the fabrication cost of silicon carbide substrate 1 can be reduced. From the standpoint of removing any damage layer in the proximity of the surface formed by slicing or the like in the production of base substrate 10 and SiC substrate 20, a step of removing a damage layer by etching, for example may be carried out instead of step S20, or step S30 that will be described afterwards may be carried out after step S20 is carried out.

At step S30, a stacking step is carried out. In this step S30, base substrate 10 qualified as a silicon carbide source is arranged to face one main face of SiC substrate 20 within a crucible 70 identified as the vessel, so that one main face 10A of base substrate 10 and one main face 20B of SiC substrate 20 face each other in contact. Specifically, referring to FIG. 2, SiC substrate 20 is placed so as to form contact on main face 10A of base substrate 10 to produce a stacked substrate 2. Main face 20A of SiC substrate 20 at the side opposite to base substrate 10 may have an off angle greater than or equal to 50° and less than or equal to 65° relative to the {0001} plane. Accordingly, a silicon carbide substrate 1 having a main face 20A of SiC layer 20 whose off angle relative to the {0001} is greater than or equal to 50° and less than or equal to 65° can be fabricated readily (refer to FIG. 3 that will be described afterwards). Further, the angle between the off orientation of main face 20A and the <1-100> direction may be less than or equal to 5°. Accordingly, formation of an epitaxial growth layer on the produced silicon carbide substrate 1 (on main face 20A) can be facilitated. Further, the off angle of main face 20A relative to the {03-38} plane in the <1-100> direction may be greater than or equal to −3° and less than or equal to 5°. Accordingly, the channel mobility when an MOSFET is produced using such a fabricated silicon carbide substrate 1 can be further improved.

The angle between the off orientation of main face 20A and the <11-20> direction may be less than or equal to 5°. Accordingly, formation of an epitaxial growth layer on the produced silicon carbide substrate 1 can be facilitated.

Then, a connecting step is carried out as step S40. In this step S40, base substrate 10 in crucible 70 is heated to a temperature range greater than or equal to the sublimation temperature of silicon carbide constituting the base substrate. Accordingly, a base layer made of silicon carbide is formed so as to contact one main face 20B of SiC substrate 20. In other words, stacked substrate 2 is heated to cause connection between base substrate 10 and SiC substrate 20 to form a base layer.

Referring to FIG. 2, as the material constituting crucible 70, graphite, tantalum carbide, or the like can be employed. In crucible 70, a projection 71 protruding from bottom face 70A towards top wall 70B may be arranged. Stacked substrate 2 is arranged at one side and a silicon generation source 91 formed of a substance including silicon is arranged at the other side with projection 71 located therebetween. In the present embodiment, silicon generation source 91 is made of elemental silicon. As the material constituting silicon generation source 91, silicon carbide, silicon nitride, or the like may be employed besides silicon. The heating of stacked substrate 2 to a temperature range greater than or equal to the sublimation temperature of silicon carbide causes base substrate 10 and SiC substrate 20 to be connected. In other words, the aforementioned connection is performed under the state where silicon generation source 91 is arranged in crucible 70. At this stage, silicon generation source 91 is heated to a temperature range where silicon is vaporized. By the procedure set forth above, the method of fabricating a silicon carbide substrate according to the present embodiment is completed. Silicon carbide substrate 1 shown in FIG. 3 is obtained.

The method of fabricating a silicon carbide substrate set forth above may further include the step of polishing a main face of SiC substrate 20 at stacked substrate 2 corresponding to main face 20A at the side opposite to base substrate 10. Accordingly, an epitaxial growth layer of high quality can be formed on main face 20A of SiC layer 20 (SiC substrate 20) at the side opposite to base substrate 10. As a result, there can be fabricated a semiconductor device including the epitaxial growth layer of high quality as, for example, an active layer. By employing such a step, there can be obtained a silicon carbide substrate 1 that allows fabrication of a semiconductor device of high quality including an epitaxial layer grown on SiC layer 20. The polishing of main face 20A of SiC substrate 20 may be carried out after connection of base substrate 10 with SiC substrate 20, or prior to the step of producing a stacked substrate by polishing in advance the main face of SiC substrate 20 that will be main face 20A at the side opposite to base substrate 10 in the stacked substrate.

Referring to FIG. 3, a silicon carbide substrate 1 obtained by the above-described fabrication method includes a base layer 10 made of silicon carbide, and a SiC layer 20 made of single crystal silicon carbide, differing from base layer 10. The event of SiC layer 20 attaining a state made of single crystal silicon carbide, differing from base layer 10, includes the case where base layer 10 is made of silicon carbide other than single crystal such as polycrystal or amorphous silicon carbide, and where base layer 10 is made of single crystal silicon carbide, differing from the crystal of SiC layer 20. The event of base layer 10 and SiC layer 20 in a state made of different crystals implies that there is a boundary between base layer 10 and SiC layer 20, and the defect density differs between one side and the other side of the boundary. At this stage, the default density may be discontinuous at the relevant boundary.

According to a method of fabricating a silicon carbide substrate 1 of the present embodiment, silicon carbide substrate 1 can be set to have a desired shape and size by the selection of the shape and the like of base substrate 10. Therefore, a silicon carbide substrate 1 that can contribute to improving the efficiency in fabricating a semiconductor device can be produced. By virtue of a silicon carbide substrate 1 fabricated according to such a process, there can be fabricated a semiconductor device utilizing a SiC substrate 20 made of high-quality silicon carbide single crystal that could not be conventionally utilized since it could not be worked to a desired shape. Therefore, silicon carbide single crystal can be used effectively. As a result, according to a method of fabricating a silicon carbide substrate 1 of the present embodiment, a silicon carbide substrate 1 that allows the fabrication cost of a semiconductor device employing the silicon carbide substrate to be reduced can be fabricated.

In the method of fabricating a silicon carbide substrate 1 of the present embodiment, a silicon generation source 91 is arranged in crucible 70 that is a vessel where connection is carried out, in addition to base substrate 10 and SiC substrate 20. Accordingly, vaporization of silicon constituting silicon generation source 91 causes the vapor pressure of the silicon gas in crucible 70 to be increased. Therefore, carbonization (conversion to graphite) at the surface of base substrate 10 and SiC substrate 20 caused by selective disengagement of silicon from base substrate 10 and SiC substrate 20 can be suppressed. As a result, the connection between base substrate 10 and SiC substrate 20 by the sublimation and recrystallization of silicon carbide proceeds smoothly.

In the method of fabricating a silicon carbide substrate 1 according to the present embodiment, base substrate 10 may be heated to a temperature higher than SiC substrate 20 in step S40. Accordingly, connection between base substrate 10 and SiC substrate 20 is achieved by the sublimation and recrystallization of silicon carbide mainly constituting base substrate 10. As a result, there can be produced a silicon carbide substrate 1 while maintaining the quality such as crystallinity of SiC substrate 20.

In the case where base substrate 10 is made of single crystal silicon carbide, base layer 10 in the obtained silicon carbide substrate shown in FIG. 3 will be made of single crystal silicon carbide. In the case where base substrate 10 is made of polycrystal silicon carbide, amorphous silicon carbide, silicon carbide sintered compact, or the like, only the region formed by sublimation of silicon carbide constituting base substrate 10 to be recrystallized on SiC substrate 20 becomes single crystal layer 10B made of single crystal silicon carbide. In other words, in such a case, there is obtained a silicon carbide substrate 1 including a single crystal layer 10B made of single crystal silicon carbide such that base layer 10 includes main face 10A at a side facing SiC layer 20, as shown in FIG. 3. In this case, in the process of fabricating a semiconductor device using silicon carbide substrate 1, a state of great thickness facilitating handling may be maintained initially in the fabrication process, and then non-single crystal region 10C that is a region other than single crystal layer 10B in base layer (base substrate) 10 may be removed during the fabrication process to allow only single crystal layer 10B of base layer 10 to remain in the semiconductor device. Accordingly, there can be fabricated a semiconductor device of high quality while facilitating handling of silicon carbide substrate 1 in the fabrication process.

At step S40 in the method of fabricating a silicon carbide substrate 1 of the present embodiment, the stacked substrate may be heated in an atmosphere obtained by reducing an ambient air atmosphere. Accordingly, the fabrication cost of silicon carbide substrate 1 can be reduced.

Furthermore, at step S40 in the method of fabricating a silicon carbide substrate 1 of the present embodiment, the stacked substrate may be heated under a pressure higher than 10⁻¹ Pa and lower than 10⁴ Pa. Accordingly, the aforementioned connection can be achieved by a simple apparatus while an atmosphere to carry out the connection in a relatively short time can be obtained. As a result, the fabrication cost of silicon carbide substrate 1 can be reduced.

At the stacked substrate produced at step S30, the gap between base substrate 10 and SiC substrate 20 is preferably less than or equal to 100 μm. Accordingly, uniform connection between base substrate 10 and SiC substrate 20 can be achieved at step S40.

The heating temperature of the stacked substrate at step S40 is preferably greater than or equal to 1800° C. and less than or equal to 2500° C. If the heating temperature is lower than 1800° C., the connection of base substrate 10 with SiC substrate 20 will become time consuming, degrading the fabrication efficiency of silicon carbide substrate 1. If the heating temperature exceeds 2500° C., the surface of base substrate 10 and SiC substrate 20 will be roughened, leading to the possibility of increasing the generation of crystal defects at the produced silicon carbide substrate 1. In order to improve the fabrication efficiency while further suppressing generation of defects at silicon carbide substrate 1, the heating temperature of the stacked substrate at step S40 is preferably greater than or equal to 1900° C. and less than or equal to 2100° C.

The atmosphere during the heating at step S40 may be inert gas atmosphere. In the case where inert gas atmosphere is employed for the atmosphere, the inert gas atmosphere preferably includes at least one selected from the group consisting of argon, helium, and nitrogen.

### Second Embodiment

A second embodiment that is another embodiment of the present invention will be described. Referring to FIG. 4, a method of fabricating a silicon carbide substrate according to the second embodiment is basically carried out by procedures similar to those of the method of fabricating a silicon carbide substrate according to the first embodiment, and provides similar effects. The method of fabricating a silicon carbide substrate of the second embodiment differs from that of the first embodiment in the configuration of crucible 70 used in heating stacked substrate 2 for the formation of base layer 10.

Referring to FIG. 4, crucible 70 is made of graphite. At the inner wall of crucible 70, a coating layer 72 suppressing the reaction between graphite constituting crucible 70 and silicon is formed. The coating layer may include at least one substance selected from the group consisting of tantalum, tantalum carbide, and silicon carbide, stable at high temperature, and having low reactivity with silicon.

Accordingly, reaction between silicon vapor and carbon (graphite) constituting crucible 70 can be suppressed. As a result, the carbonization of base substrate 10 qualified as a silicon carbide source and SiC substrate 20 can be suppressed further effectively.

### Third Embodiment

A third embodiment that is another embodiment of the present invention will be described hereinafter with reference to FIGS. 5-7. The fabrication method of a silicon carbide substrate according to the third embodiment is carried out in a manner basically similar to that of the first embodiment. The method of fabricating a silicon carbide substrate of the third embodiment differs from that of the first embodiment in the formation process of the base layer.

Referring to FIG. 5, in the fabrication method of a silicon carbide substrate of the third embodiment, a substrate preparation step is carried out as step S10. At step S10, SiC substrate 20 is prepared in a manner similar to that of the first embodiment, and a material substrate 11 made of silicon carbide is prepared. Material substrate 11 may be made of single crystal silicon carbide, or of polycrystal silicon carbide or amorphous silicon carbide, or a silicon carbide sintered compact. Alternatively, raw material powder of silicon carbide can be employed instead of material substrate 11.

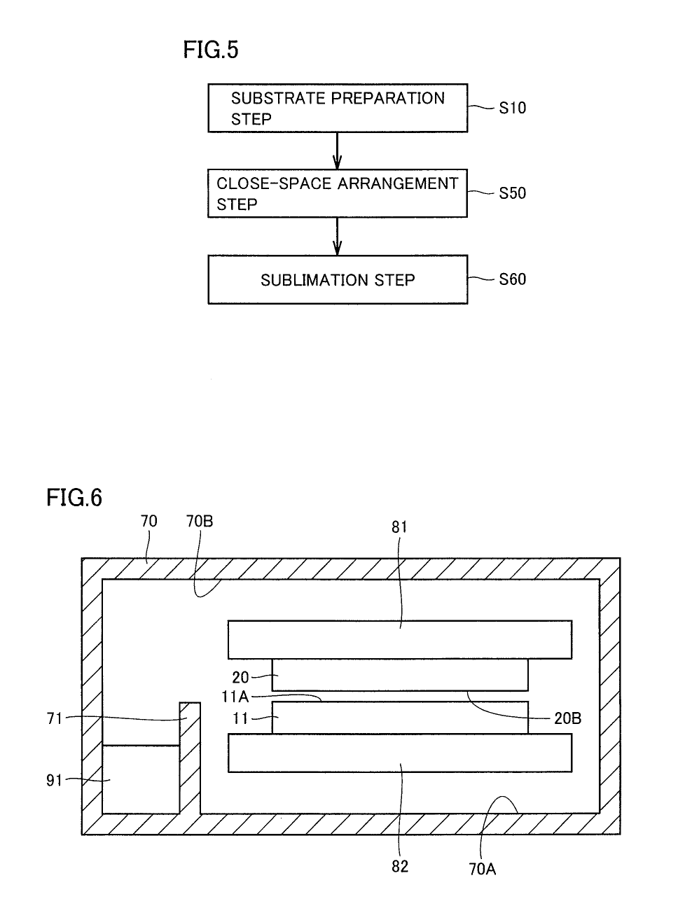

Then, a close-space arrangement step is carried out at step S50. At this step S50, SiC substrate 20 and material substrate 11 are held by a first heater 81 and a second heater 82, respectively, arranged in heating vessel 70 facing each other, as shown in FIG. 6. Specifically, at step S50, material substrate 11 made of silicon carbide, qualified as a silicon carbide source, is arranged such that one main face 11 A of material substrate 11 and one main face 20B of SiC substrate 20 face each other with a distance therebetween.

The appropriate value of the distance between SiC substrate 20 and material substrate 11 is considered to be related with the mean free path of the sublimation gas during heating in step S60 that will be described afterwards. Specifically, the average value of the distance between SiC substrate 20 and material substrate 11 can be set to be smaller than the mean free path of the sublimation gas during heating in step S60. For example, under the pressure of 1 Pa and temperature of 2000° C., the mean free path of the atoms and molecules is present in approximately several to several ten centimeters, depending upon the atomic radius and molecular radius, strictly speaking. Therefore, in practice, the aforementioned distance is preferably set less than or equal to several centimeters. More specifically, SiC substrate 20 and material substrate 11 are arranged in close proximity such that their main surfaces face each other with the distance therebetween greater than or equal to 1 μm and less than or equal to 1 cm. By setting the average value of the distance less than or equal to 1 cm, the film thickness distribution of base layer 10 formed in step S60 that will be described afterwards can be reduced. Furthermore, by setting the average value of the distance less than or equal to 1 mm, the film thickness distribution of base layer 10 formed in step S60 that will be described afterwards can be further reduced. Moreover, by setting the average value of the distance greater than or equal to 1 μm, sufficient space for sublimation of silicon carbide can be ensured.

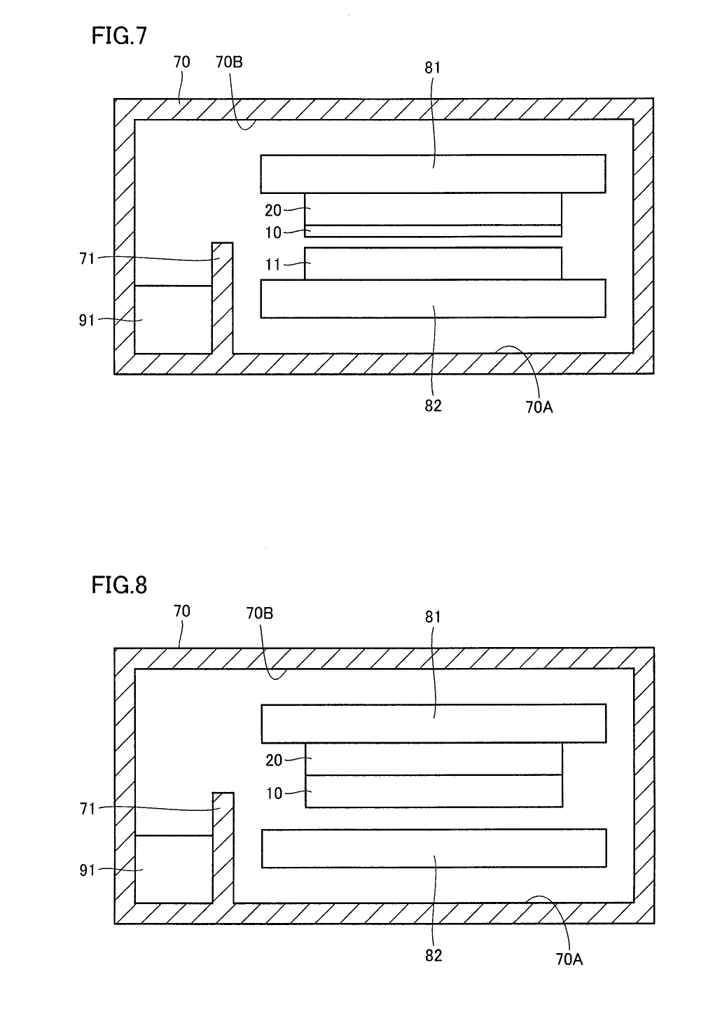

Then, a sublimation step is performed as step S60. In step S60, SiC substrate 20 is heated up to a predetermined substrate temperature by first heater 81. Material substrate 11 is heated up to a predetermined material temperature by second heater 82. At this stage, the heating of material substrate 11 up to the material temperature causes sublimation of silicon carbide from the surface of the material substrate. The substrate temperature is set lower than the material temperature. Specifically, the substrate temperature is set lower by at least 1° C. and not more than 100° C. than the material temperature. The substrate temperature is, for example, higher than or equal to 1800° C. and less than or equal to 2500° C. Accordingly, silicon carbide attaining a gaseous state by sublimation from material substrate 11 arrives at the surface of SiC substrate 20 to attain a solid phase to form base layer 10, as shown in FIG. 7. At this stage, silicon generation source 91 arranged in a manner similar to that of the first embodiment is heated up to the temperature range where silicon is vaporized.

By maintaining this state, the SiC constituting material substrate 11 is completely sublimed to move onto the surface of SiC substrate 20, as shown in FIG. 8. Thus, step S60 is completed. A silicon carbide substrate 1 similar to that of the first embodiment described with reference to FIG. 3 is completed. In the present embodiment, a predetermined distance is formed between SiC substrate 20 and material substrate 11, as set forth above. Therefore, according to the method of fabricating a silicon carbide substrate of the present embodiment, the formed base layer 10 is made of single crystal silicon carbide, even in the case where the material substrate identified as a silicon carbide source is made of polycrystal silicon carbide, amorphous silicon carbide, a silicon carbide sintered compact, or the like.

### Fourth Embodiment

A fourth embodiment that is still another embodiment of the present invention will be described hereinafter. The method of fabricating a silicon carbide substrate of the fourth embodiment is carried out by procedures basically similar to those of the method of fabricating a silicon carbide substrate of the first embodiment, and provides similar effects. However, the method of fabricating a silicon carbide substrate of the fourth embodiment differs from the first embodiment in that a plurality of SiC substrates 20 are arranged in alignment in plan view at step S30.

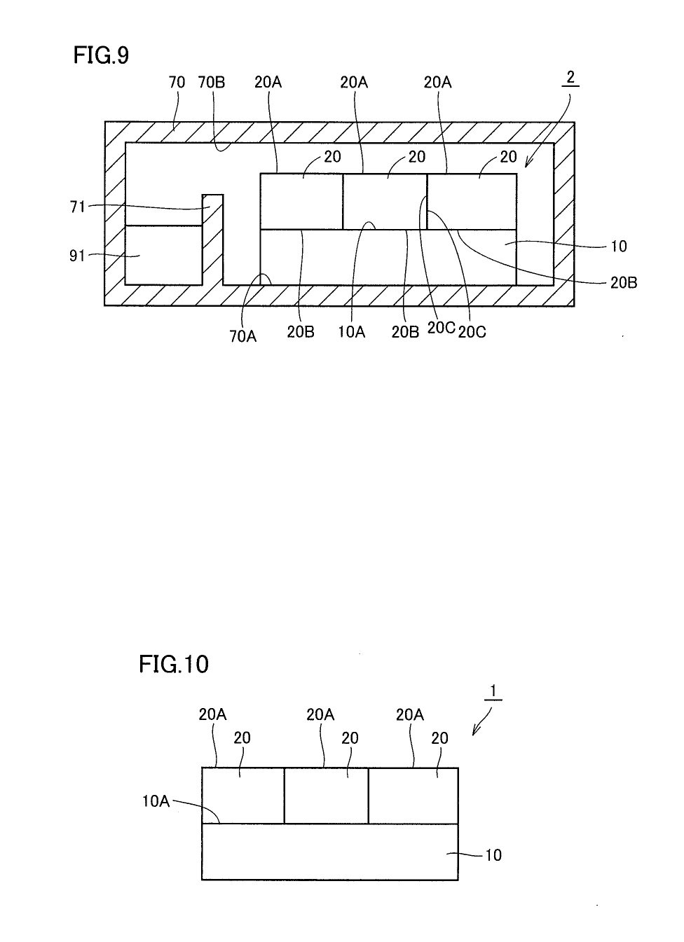

In the method of fabricating a silicon carbide substrate of the present embodiment, a base substrate 10 is prepared in a manner similar to that of the first embodiment at step (S10). In addition, a plurality of SiC substrates 20 are prepared. Then, step S20 is carried out, if necessary, as in the first embodiment. Referring to FIG. 9, SiC substrates 20 are arranged in alignment in plan view on main face 10A of base substrate 10 at step S30 to produce a stacked substrate. In other words, SiC substrates 20 are arranged in alignment along main face 10A of base substrate 10.

More specifically, SiC substrates 20 may be arranged in a matrix such that SiC substrates 20 adjacent on main face 10A of base substrate 10 contact each other. Then, step S40 is carried out as in the first embodiment to obtain silicon carbide substrate 1. In the present embodiment, a plurality of SiC substrates 20 are mounted on base substrate 10 at step S30. The plurality of SiC substrates 20 and base substrate 10 are connected at step S40. Referring to FIG. 10, according to a method of fabricating a silicon carbide substrate of the present embodiment, a silicon carbide substrate 1 that can be handled as a substrate of large diameter having SiC layer 20 of high quality can be fabricated. By using such a silicon carbide substrate 1, the fabrication process of a semiconductor device can be increased in efficiency.

Referring to FIG. 9, an end face 20C of SiC substrate 20 is preferably substantially vertical to main face 20A of SiC substrate 20. Accordingly, fabrication of silicon carbide substrate 1 is facilitated. If the angle between end face 20C and main face 20A is greater than or equal to 85° and less than or equal to 95°, a determination can be made that end face 20C and main face 20A are substantially perpendicular to each other.

### Fifth Embodiment

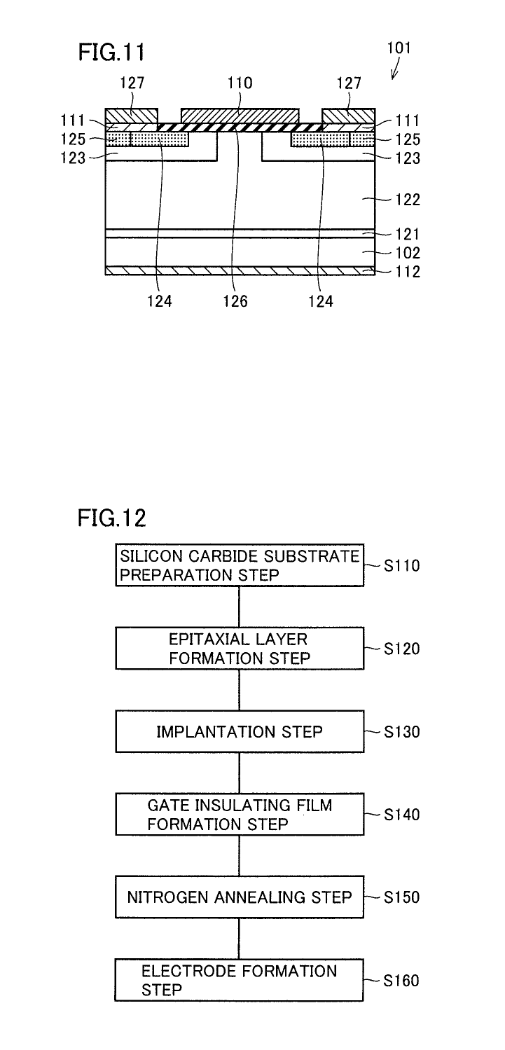

An example of a semiconductor device produced using a silicon carbide substrate of the present invention set forth above will be described as the fifth embodiment. Referring to FIG. 11, a semiconductor device 101 of the present invention is a vertical double implanted MOSFET (DiMOSFET), including a substrate 102, a buffer layer 121, a breakdown voltage holding layer 122, a p region 123, an n⁺ region 124, a p⁺ region 125, an oxide film 126, a source electrode 111 and an upper source electrode 127, a gate electrode 110, and a drain electrode 112 formed at the backside of substrate 102. Specifically, buffer layer 121 made of silicon carbide is formed on the surface of substrate 102 made of n type conductivity silicon carbide. For substrate 102, a silicon carbide substrate fabricated according to a method of fabricating a silicon carbide substrate of the present invention including the method described in the first to fourth embodiments set forth above is employed. In the case where silicon carbide substrate 1 of the first to fourth embodiments is employed, buffer layer 121 is formed on SiC layer 20 of silicon carbide substrate 1. Buffer layer 121 has an n type conductivity, and a thickness of 0.5 μm, for example. The concentration of n conductivity type impurities in buffer layer 121 is set at 5×10¹⁷ cm⁻³, for example. Breakdown voltage holding layer 122 is formed on buffer layer 121. Breakdown voltage holding layer 122 is made of n type conductivity silicon carbide, and has a thickness of 10 μm, for example. The concentration of n conductivity type impurities in breakdown voltage holding layer 122 may take the value of 5×10¹⁵ cm⁻³, for example.

At the surface of breakdown voltage holding layer 122, p regions 123 having p type conductivity are formed spaced apart from each other. In p region 123, n⁺ region 124 is formed at the surface layer of p region 123. At a region adjacent to this n⁺ region 124, p⁺ region 125 is formed. There is also an oxide film 126 formed extending from above n⁺ region 124 at one of p regions 123, over p region 123, a region of breakdown voltage holding layer 122 exposed between the two p regions 123, the other p region 123, as far as above n⁺ region 124 at the relevant other p region 123. Gate electrode 110 is formed on oxide film 126. Source electrode 111 is formed on n⁺ region 124 and p⁺ region 125. Upper source electrode 127 is formed on source electrode 111. Substrate 102 has drain electrode 112 formed at a backside surface that is the surface opposite to the surface where buffer layer 121 is formed.

In semiconductor device 101 of the present embodiment, a silicon carbide substrate fabricated according to a method of fabricating a silicon carbide substrate of the present invention including the method described in the first to fourth embodiments of the present invention is employed as substrate 102. Specifically, semiconductor device 101 includes substrate 102 as the silicon carbide substrate, buffer layer 121 and breakdown voltage holding layer 122 as the epitaxial grown layer formed by on substrate 102, and source electrode 111 formed on breakdown voltage holding layer 122. Substrate 102 is fabricated according to a method of fabricating a silicon carbide substrate of the present invention. The substrate fabricated according to a method of fabricating a silicon carbide substrate of the present invention is a silicon carbide substrate capable of reducing the fabricating cost of a semiconductor device. Therefore, semiconductor device 101 is a semiconductor device having the fabricating cost reduced.

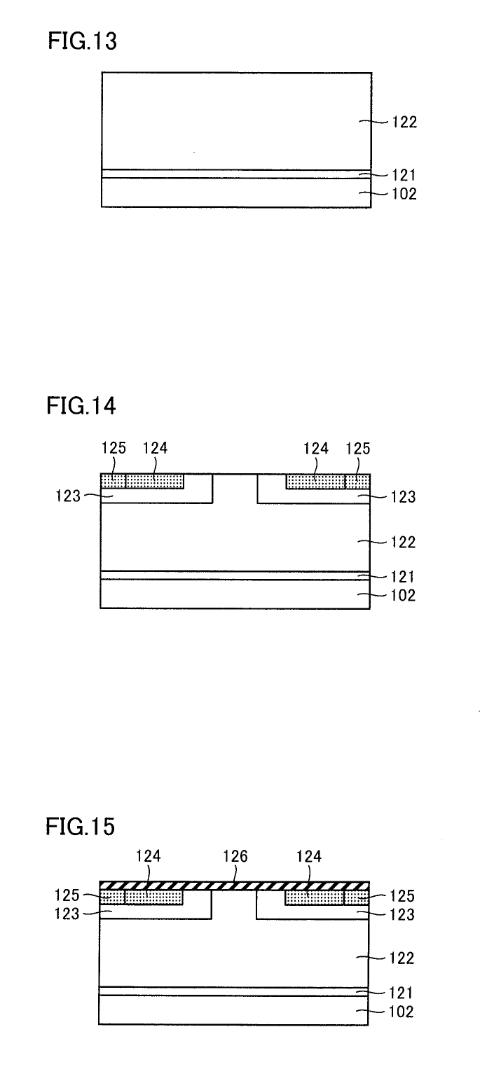

A method for fabricating semiconductor device 101 of FIG. 11 will be described hereinafter with reference to FIGS. 12-16. Referring to FIG. 12, first a silicon carbide substrate preparation step (S110) is performed. At this stage, a substrate 102 made of silicon carbide, having the (03-38) plane as the main surface (refer to FIG. 13), is prepared. For substrate 102, a silicon carbide substrate of the present invention including silicon carbide substrate 1 fabricated by the fabricating method described in the first to fourth embodiments set forth above is prepared as substrate 102.

For substrate 102 (refer to FIG. 13), a substrate having n type conductivity and a substrate resistance of 0.02 Ωcm may be employed.

Then, as shown in FIG. 12, an epitaxial layer formation step (S120) is performed. Specifically, buffer layer 121 is formed on the surface of substrate 102. This buffer layer 121 is formed on main face 20A of SiC layer 20 of silicon carbide substrate 1 (refer to FIG. 3) employed as substrate 102. For buffer layer 121, an epitaxial layer made of silicon carbide of n type conductivity, and having a thickness of 0.5 μm, for example, is formed. The density of conductivity type impurities in buffer layer 121 may take the value of 5×10¹⁷ cm⁻³, for example. On this buffer layer 121, breakdown voltage holding layer 122 is formed, as shown in FIG. 13. For breakdown voltage holding layer 122, a layer of n type conductivity silicon carbide can be formed by epitaxial growth. The thickness of breakdown voltage holding layer 122 may take the value of 10 μm, for example. The density of n conductivity type impurities in breakdown voltage holding layer 122 may take the value of 5×10¹⁵ cm⁻³, for example.

Then, an implantation step (S130) shown in FIG. 12 is performed. Specifically, using an oxide film formed by photolithography and etching as a mask, impurities of p type conductivity are implanted into breakdown voltage holding layer 122 to form p region 123, as shown in FIG. 14. Following removal of the oxide film used, a new oxide film having a pattern is formed by photolithography and etching. Using this oxide film as a mask, n conductivity type impurities are implanted into a predetermined region to form n⁺ region 124. Further, by implanting p conductivity type impurities through a similar procedure, p⁺ region 125 is formed. As a result, the configuration as shown in FIG. 14 is obtained.

Following the implantation step, an activation annealing process is performed. For this activation annealing process, the conditions including a heating temperature of 1700° C., and a heating duration of 30 minutes, using argon gas, for example, as the atmosphere gas, may be employed.

Then, a gate insulating film formation step (S140) is performed, as shown in FIG. 12. Specifically, oxide film 126 is foamed on to cover breakdown voltage holding layer 122, p region 123, n⁺ region 124, and p⁺ region 125, as shown in FIG. 15. The condition for forming oxide film 126 may include, for example, dry oxidation (thermal oxidation). The conditions of this dry oxidation including a heating temperature of 1200° C. and a heating duration of 30 minutes may be employed.

Then, a nitrogen annealing step (S150) is performed, as shown in FIG. 12. Specifically, annealing is performed with nitric oxide (NO) as the atmosphere gas. The annealing conditions include, for example, 1100° C. for the heating temperature and 120 minutes for the heating duration. As a result, nitrogen atoms are introduced in the proximity of the interface between oxide film 126 and underlying breakdown voltage holding layer 122, p region 123, n⁺ region 124 and p⁺ region 125. Following this annealing step using nitric oxide as the atmosphere gas, further annealing using argon (Ar) as the inert gas may be performed. Specifically, the conditions including a heating temperature of 1100° C. and a heating duration of 60 minutes, using argon gas as the atmosphere gas, may be employed.

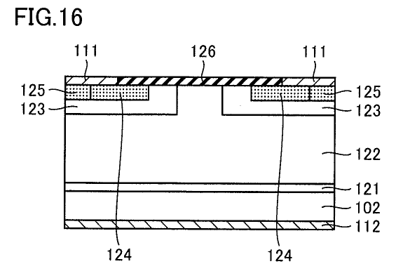

Then, an electrode formation step (S160) indicated in FIG. 12 is performed. Specifically, a resist film having a pattern is formed by photolithography on oxide film 126. Using this resist film as a mask, the region of the oxide film located above n⁺ region 124 and p⁺ region 125 is removed by etching. Then, a conductor film such as of metal is formed in contact with n⁺ region 124 and p⁺ region 125 on the resist film and in an opening formed in oxide film 126. Then, the conductor film located on the resist film is removed (lift off) by removing the resist film. Nickel (Ni), for example, may be employed for the conductor. As a result, source electrode 111 can be obtained, as shown in FIG. 16. At this stage, a heat treatment is preferably carried out for alloying. Specifically, a heat treatment (alloying process) is carried out at a heating temperature of 950° C. and a heating duration of 2 minutes using argon (Ar) gas that is inert gas for the atmosphere gas.

Then, upper source electrode 127 (refer to FIG. 11) is formed on source electrode 111. Further, gate electrode 110 (refer to FIG. 11) is formed on oxide film 126. Also, drain electrode 112 is formed. Thus, semiconductor device 101 shown in FIG. 11 can be obtained.

Although a vertical MOSFET has been described as an example of a semiconductor device that can be produced using the silicon carbide substrate of the present invention in the fifth embodiment set forth above, the semiconductor device that can be produced is not limited thereto. Various semiconductor devices such as a junction field effect transistor (JFET), an insulated gate bipolar transistor (IGBT), or a Schottky barrier diode can be produced using a silicon carbide substrate of the present invention.

Furthermore, although the fifth embodiment has been described based on a semiconductor device being produced by forming an epitaxial layer functioning as an operation layer on a silicon carbide substrate with the (03-38) plane as the main surface, the crystal plane that can be employed for the main surface is not limited thereto. An arbitrary crystal plane according to the usage, including the (0001) plane, may be employed for the main face.

Furthermore, by employing a main surface having an off angle relative to the (0-33-8) plane in the <01-10> direction greater than or equal to −3° and less than or equal to +5° as the main surface (main face 20A of SiC substrate (SiC layer) 20 of silicon carbide substrate 1), the channel mobility in the case of producing a MOSFET or the like using a silicon carbide substrate can be further improved. As used herein, the (0001) plane and the (000-1) plane of the hexagonal single crystal silicon carbide are defined as the silicon plane and the carbon plane, respectively. Further, “the off angle relative to the (0-33-8) plane in the <01-10> direction” refers to the angle between the orthogonal projection of the normal line of the main surface on the plane defined by the <000-1> direction and the <01-10> direction as the reference of the off orientation, and the normal line of the (0-33-8) plane. The sign is positive when the aforementioned orthogonal projection approaches the <01-10> direction in parallel, and negative when the aforementioned orthogonal projection approaches the <000-1> direction in parallel. A main surface having an off angle relative to the (0-33-8) plane in the <01-10> direction greater than or equal to −3° and less than or equal to +5° implies a plane on the carbon plane side satisfying the aforementioned conditions in the silicon carbide crystal. The (0-33-8) plane in the present application includes the plane of the equivalent carbon plane side differing in representation by the setting of the axis to define the crystal plane, and does not include a plane of the silicon plane side.

### EXAMPLE

In order to confirm the effects of a method of fabricating a silicon carbide substrate of the present invention, experiments were carried out on fabricating a silicon carbide substrate under procedures similar to those of the fourth embodiment. The experiments were carried out as set forth below.

As a base substrate, a substrate made of single crystal silicon carbide was prepared, having a diameter φ of 6 inches, a thickness of 400 μm, 4 H polytype, a main face of {03-38} plane, n type impurity concentration of 1×10²⁰ cm⁻³, micropipe density of 1×10⁴ cm⁻², and stacking defect density of 1×10⁵ cm⁻¹. For the SiC substrate, a substrate made of single crystal silicon carbide was prepared, having a square shape with one side of 20 mm, a thickness of 200 μm, 4 H polytype, a main face of {03-38} plane, n type impurity concentration of 1×10¹⁹ cm⁻³, micropipe density of 0.2 cm⁻², and a stacking fault density less than 1 cm⁻¹.

Then, a plurality of SiC substrates were arranged in alignment on base substrate without overlapping each other, taken as a stacked substrate, and placed in a graphite vessel (crucible). Furthermore, elemental silicon was arranged in the crucible as a silicon generation source. The stacked substrate was heated greater than or equal to 2000° C. Also, the silicon generation source was heated for vaporization of silicon to connect to the base substrate with the SiC substrates. For comparison, experiments were carried out corresponding to the case where a silicon generation source was not arranged based on similar procedures.

As a result, by virtue of arranging a silicon generation source, conversion into graphite in the proximity of the surface of the base substrate and SiC substrate was suppressed, as compared to the case where a silicon generation source was not arranged. Favorable connection between the base substrate and SiC substrate was achieved. This is probably because the vapor pressure of gas with the silicon in the crucible as a constituent element rises by the silicon gas from the silicon generation source to suppress the selective (preferential) disengagement of silicon.

In the method of fabricating a silicon carbide substrate, a method of fabricating a semiconductor device, a silicon carbide substrate, and a semiconductor device of the present invention set forth above, the diameter of the base substrate (base layer) is preferably greater than or equal to 2 inches, more preferably greater than or equal to 6 inches. Taking into account an application to a power device, the polytype of silicon carbide constituting the SiC layer (SiC substrate) is preferably 4 H. Further, the crystal structure of the base substrate and SiC substrate is preferably the same. The difference in the thermal expansion between the base layer and the SiC layer is preferably at a small level that avoids generation of a crack in the fabrication process of a semiconductor device employing a silicon carbide substrate. The variation in the in-plane thickness at each of the base substrate and SiC substrate is preferably small. Specifically, the variation in the relevant thickness is preferably less than or equal to 10 μm. In consideration of an application to a vertical device in which current flows in the direction of the thickness of the silicon carbide substrate, the electrical resistivity of the base layer is preferably less than 50 mΩcm, preferably less than 10 mΩcm. From the standpoint of facilitating handling, the thickness of the silicon carbide substrate is preferably greater than or equal to 300 μm. Resistance heating, high frequency induction heating, lamp annealing, or the like can be employed to heat the base substrate in the step of forming a base layer.

It is to be understood that the embodiments and examples disclosed herein are only by way of example, and not to be taken by way of limitation. The scope of the present invention is not limited by the description above, but rather by the terms of the appended claims, and is intended to include any modifications within the scope and meaning equivalent to the terms of the claims.

### INDUSTRIAL APPLICABILITY

A method of fabricating a silicon carbide substrate, a method of fabricating a semiconductor device, a silicon carbide substrate, and a semiconductor device of the present invention are particularly applicable advantageously to a method of fabricating a silicon carbide substrate requiring reduction in the fabrication cost of a semiconductor device employing a silicon carbide substrate, a method of fabricating a semiconductor device, a silicon carbide substrate, and a semiconductor device of the present invention.

### REFERENCE SIGNS LIST

1 silicon carbide substrate; 2 stacked substrate; 10 base layer (base substrate); 10A main face; 10B single crystal layer; 10C non-single crystal region; 11 material substrate; 11A main face; 20 SiC layer (SiC substrate); 20A, 20B main face; 20C end face; 70 crucible (heating vessel); 70A bottom wall; 70B top wall; 71 projection; 72 coating layer; 81 first heater; 82 second heater; 91 silicon generation source; 101 semiconductor device; 102 substrate; 110 gate electrode; 111 source electrode; 112 drain electrode; 121 buffer layer; 122 breakdown voltage holding layer; 123 p region; 124 n⁺ region; 125 p⁺ region, 126 oxide film; 127 upper source electrode.

1. A method of fabricating a silicon carbide substrate comprising the steps of:
preparing a SiC substrate made of single crystal silicon carbide,
arranging a silicon carbide source in a vessel so as to face one main face of said SiC substrate, and
forming a base layer made of silicon carbide so as to contact one main face of said SiC substrate by heating said silicon carbide source in said vessel to a temperature range greater than or equal to a sublimation temperature of silicon carbide constituting said silicon carbide source,
in said step of forming a base layer, a silicon generation source made of a substance containing silicon is arranged in said vessel, in addition to said SiC substrate and said silicon carbide source.

2. The method of fabricating a silicon carbide substrate according to claim 1, wherein graphite is employed as a material constituting said vessel.

3. The method of fabricating a silicon carbide substrate according to claim 2, wherein a coating layer is formed at an inner wall of said vessel to suppress reaction between graphite constituting said vessel and silicon.

4. The method of fabricating a silicon carbide substrate according to claim 3, wherein said coating layer includes at least any one substance selected from the group consisting of tantalum, tantalum carbide and silicon carbide.

5. The method of fabricating a silicon carbide substrate according to claim 1, wherein said vessel is made of tantalum carbide.

6. The method of fabricating a silicon carbide substrate according to claim 1, wherein
in said step of preparing a SiC substrate, a plurality of said SiC substrates are prepared,
in said step of arranging a silicon carbide source, said silicon carbide source is arranged with a plurality of said SiC substrates arranged in alignment in plan view,
in said step of forming a base layer, said base layer is formed such that one main faces of a plurality of said SiC substrates are connected with each other.

7. The method of fabricating a silicon carbide substrate according to claim 1, wherein
in said step of arranging a silicon carbide source, a base substrate made of silicon carbide qualified as a silicon carbide source is arranged such that one main face of said base substrate and one main face of said SiC substrate face each other in contact, and
in said step of forming a base layer, said base substrate is heated for connection of said base substrate with said SiC substrate to form said base layer.

8. The method of fabricating a silicon carbide substrate according to claim 7, further comprising the step of planarizing main faces of said base substrate and said SiC substrate to be brought into contact with each other at said step of arranging said silicon carbide source, prior to said step of arranging a silicon carbide source.

9. The method of fabricating a silicon carbide substrate according to claim 7, wherein said step of arranging a silicon carbide source is carried out without polishing main faces of said base substrate and said SiC substrate to be brought into contact with each other, prior to said step of arranging a silicon carbide source.

10. The method of fabricating a silicon carbide substrate according to claim 1, wherein
in said step of arranging a silicon carbide source, a material substrate made of silicon carbide qualified as said silicon carbide source is arranged such that one main face of said material substrate and one main face of said SiC substrate face each other with a distance therebetween, and
in said step of forming a base layer said material substrate is heated to cause sublimation of silicon carbide constituting said material substrate to form said base layer.

11. The method of fabricating a silicon carbide substrate according to claim 1, wherein, in said step of forming a base layer, said base layer is formed such that a main face of said SiC substrate at a side opposite to said base layer has an off angle greater than or equal to 50° and less than or equal to 65° relative to a {0001} plane.

12. The method of fabricating a silicon carbide substrate according to claim 11, wherein, in said step of forming a base layer, said base layer is formed such that an angle between an off orientation of a main face of said SiC substrate at a side opposite to said base layer and a <1-100> direction is less than or equal to 5°.

13. The method of fabricating a silicon carbide substrate according to claim 12, wherein, in said step of forming a base layer, said base layer is formed such that an off angle of a main face of said SiC substrate at a side opposite to said base layer, relative to a {03-38} plane in a <1-100> direction is greater than or equal to −3° and less than or equal to 5°.

14. The method of fabricating a silicon carbide substrate according to claim 11, wherein, in said step of forming a base layer, said base layer is formed such that an angle between an off orientation of a main face of said SiC substrate at a side opposite to said base layer and a <11-20> direction is less than or equal to 5°.

15. The method of fabricating a silicon carbide substrate according to claim 1, wherein, in said step of forming a base layer, said base layer is formed in an atmosphere obtained by reducing a pressure of an ambient air atmosphere.

16. The method of fabricating a silicon carbide substrate according to claim 1, wherein, in said step of forming a base layer, said base layer is formed under a pressure higher than 10⁻¹ Pa and lower than 10⁴ Pa.

17. A method of fabricating a semiconductor device comprising the steps of:
preparing a silicon carbide substrate,
forming an epitaxial growth layer on said silicon carbide substrate, and
forming an electrode on said epitaxial growth layer,
in said step of preparing a silicon carbide substrate, said silicon carbide substrate is fabricated by a method of fabricating a silicon carbide substrate defined in claim 1.

18. A silicon carbide substrate fabricated by the method of fabricating a silicon carbide substrate defined in claim 1.

19. A semiconductor device fabricated by a method of fabricating a semiconductor device defined in claim 17.
